(19) United States
(12) Patent Application Publication
(10) Pub. No.: US 2026/0246411 A1
(43) Pub. Date: Aug. 20, 2026

(54) MOTOR CONTROL APPARATUS

(71) Applicant: SANYO DENKI CO., LTD., Tokyo (JP)

(72) Inventors: Tetsuya HAYASHI, Tokyo (JP); Masanao SOMEMIYA, Tokyo (JP)

(21) Appl. No.: 19/429,600

(22) Filed: Dec. 22, 2025

(30) Foreign Application Priority Data
Dec. 25, 2024 (JP) 2024-228206

(51) Int. Cl. H02P 29/024; H02P 3/06; H03K 19/20

(52) U.S. Cl. CPC H02P 29/024; H02P 3/06; H03K 19/20

(57) ABSTRACT

A motor control apparatus includes: a receiving portion configured to receive a setting signal from an external apparatus of the motor control apparatus; and a composite signal generation portion configured to generate a composite signal from a plurality of state signals indicating at least one of a state of a motor and a state of the motor control apparatus, in which the composite signal generation portion is configured to determine a logical operation equation including the plurality of state signals on the basis of the setting signal, and generate the composite signal by the logical operation equation.

### CROSS-REFERENCE TO RELATED APPLICATION

This application is based on Japanese Patent Application No. 2024-228206 filed with the Japan Patent Office on Dec. 25, 2024, the entire content of which is hereby incorporated by reference.

### BACKGROUND

### 1. Technical Field

An aspect of the present disclosure relates to a motor control apparatus.

### 2. Related Art

A motor control apparatus disclosed in JP-A-2004-260890 uses a parallel arithmetic circuit to generate a composite signal being a processing signal to be processed next, on the basis of data read from a motor targeted for control. The use of the parallel arithmetic circuit enables high-speed processing in the motor control apparatus.

### SUMMARY

A motor control apparatus includes: a receiving portion configured to receive a setting signal from an external apparatus of the motor control apparatus; and a composite signal generation portion configured to generate a composite signal from a plurality of state signals indicating at least one of a state of a motor and a state of the motor control apparatus, in which the composite signal generation portion is configured to determine a logical operation equation including the plurality of state signals on the basis of the setting signal, and generate the composite signal by the logical operation equation.

### BRIEF DESCRIPTION OF DRAWINGS

FIG. 1 is a block diagram of a motor control apparatus according to a first embodiment of the present disclosure;

FIG. 2 is a flowchart illustrating a process of generating a composite signal; and

FIG. 3 is a diagram illustrating an example of a user setting screen displayed on a setting portion of an external apparatus.

### DETAILED DESCRIPTION

In the following detailed description, for purpose of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

A motor control apparatus that allows a user to generate a composite signal indicating the current states of a plurality of motors on his/her own is being required. The motor control apparatus disclosed in JP-A-2004-260890 does not include a means for generating a composite signal indicating the current states of a plurality of motors on the basis of a setting signal set by a user. Hence, in a host apparatus of the motor control apparatus, the user receives a plurality of signals indicating the current states of the motors from the motor control apparatus, and generates a composite signal on the basis of the plurality of signals. Therefore, the number of signal lines between the motor control apparatus and the host apparatus increases.

Hence, one object of the present disclosure is to provide a motor control apparatus that generates a composite signal desired by a user, the composite signal indicating at least one of the current state of a motor and the state of the motor control apparatus.

A motor control apparatus according to an aspect of the present disclosure includes: a receiving portion configured to receive a setting signal from an external apparatus of the motor control apparatus; and a composite signal generation portion configured to generate a composite signal from a plurality of state signals indicating at least one of a state of a motor and a state of the motor control apparatus, in which the composite signal generation portion is configured to determine a logical operation equation including the plurality of state signals on the basis of the setting signal, and generate the composite signal by the logical operation equation.

According to the one aspect of the present disclosure, it is possible to provide a motor control apparatus that generates a composite signal desired by a user, the composite signal indicating at least one of the current state of a motor and the state of, for example, the motor control apparatus.

An embodiment of the present disclosure is described hereinafter with reference to the drawings. Note that descriptions of members having the same reference numerals as members already described are omitted in the detailed description for convenience of description.

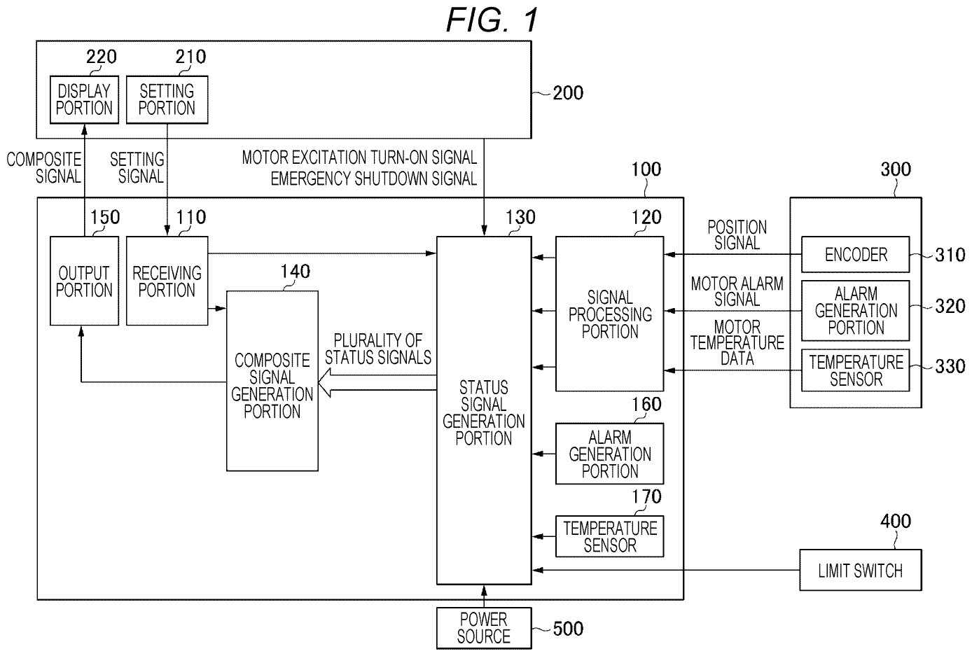

FIG. 1 is a block diagram of a motor control apparatus 100 according to a first embodiment. As illustrated in FIG. 1, the motor control apparatus 100 is connected by, for example, communication cables to an external apparatus 200 being a host apparatus of the motor control apparatus 100, a plurality of motors 300, a limit switch 400 for a drive target object of each of the motors 300, and a power source 500 for motor drive. The power source 500 for motor drive is an alternating current power source or a direct current power source, and is, for example, a commercial power source. In the exemplification of FIG. 1, a state where the motor control apparatus 100 is connected to only one motor 300 is illustrated for convenience of description. In reality, the motor control apparatus 100 is connected to the plurality of motors.

The external apparatus 200 includes a setting portion 210 and a display portion 220. The external apparatus 200 is, for example, a computer or a sequencer. The setting portion 210 transmits a setting signal set by a user to the motor control apparatus 100. The display portion 220 displays a screen in relation to a composite signal outputted from the motor control apparatus 100. The external apparatus 200 may include input devices for setting a setting signal, such as a keyboard, a mouse, and/or a touchscreen.

The user uses the external apparatus 200 to select arbitrary signals as selection signals from various state signals. Therefore, the user can cause the motor control apparatus 100 to output a composite signal being a result of a logical operation of the selection signals. The user can input a logical operation signal into the external apparatus 200. The setting signal including these instructions (the selection signals and the logical operation signal), which has been set by the user, is transmitted to the motor control apparatus 100 through the setting portion 210. Note that the selection signal is a signal indicating at least one of the state of the motor and the state of the motor control apparatus. Moreover, the logical operation signal is a signal indicating an instruction related to what logical operation equation is set by use of the selection signals. Moreover, the state signal is, for example, a binary signal.

As illustrated in FIG. 1, the external apparatus 200 may be configured in such a manner as to be capable of transmitting, to the motor control apparatus 100, a motor excitation turn-on signal indicating a control signal that instructs to turn on excitation in the motor, and/or an emergency shutdown signal that gives an emergency shutdown instruction to the motor control apparatus 100.

The motors 300 are controlled by the motor control apparatus 100. The plurality of motors 300 is, for example, multi-axis motors for transfer that transfer target objects, or drive motors for articulated robots. Each of the motors 300 includes an encoder 310, an alarm generation portion 320, and a temperature sensor 330. Each of the encoders 310 generates an analog or digital signal responsive to the rotational position of the motor 300, and transmits the signal to the motor control apparatus 100. Each of the alarm generation portions 320 generates a motor alarm signal indicating, for example, a fault occurring in the motor 300, and transmits the motor alarm signal to the motor control apparatus 100. Each of the temperature sensors 330 generates an analog or digital signal indicating the current temperature of the motor 300, and transmits the signal to the motor control apparatus 100.

The limit switch 400 is, for example, a stopper sensor. The limit switch 400 is a sensor that detects that a drive target object of the motor 300 has exceeded a movement restriction limit, and transmits the detection to the motor control apparatus 100. The limit switch 400 sets a limit signal to ON when the drive target object of the motor 300 has exceeded the movement restriction limit.

The power source 500 is a power source device that feeds power to the motor control apparatus 100. The motor control apparatus 100 converts at least one of a voltage value or current value of power supplied from the power source 500 into a digital signal, and transmits the digital signal to a state signal generation portion 130.

The motor control apparatus 100 is an apparatus that controls the motors 300. The motor control apparatus 100 has a function of generating a composite signal desired by the user, in addition to an original function of controlling the motors 300. Note that in FIG. 1, a portion that controls the motors 300 is not illustrated.

The motor control apparatus 100 includes a receiving portion 110, a signal processing portion 120, the state signal generation portion 130, a composite signal generation portion 140, an output portion 150, an alarm generation portion 160, and a temperature sensor 170.

The receiving portion 110 receives a setting signal set by the setting portion 210. The receiving portion 110 transmits selection signals in the received setting signal to the state signal generation portion 130. The receiving portion 110 transmits a logical operation signal in the received setting signal to the composite signal generation portion 140.

The signal processing portion 120 performs a conversion process on various analog signals acquired from the motors 300 into digital signals, and transmits the digital signals to the state signal generation portion 130. Note that if the motor control apparatus 100 acquires the digital signals directly from the motors 300, the signal processing portion 120 is not required. Therefore, the motor control apparatus 100 may be configured in such a manner as to transmit various digital signals from the motors 300 directly to the state signal generation portion 130.

The alarm generation portion 160 of the motor control apparatus 100 detects an anomaly in the motor control apparatus 100, and transmits a signal responsive to the anomaly to the state signal generation portion 130. For example, the alarm generation portion 160 generates a signal responsive to, for example, an anomaly in the communication state and a circuit anomaly of the motor control apparatus 100. The temperature sensor 170 of the motor control apparatus 100 generates a signal responsive to the temperature of the motor control apparatus 100, and transmits the signal responsive to the temperature to the state signal generation portion 130.

On the basis of the selection signals in the received setting signal, the state signal generation portion 130 selects state signals corresponding to the selection signals among a plurality of state signals. The state signal generation portion 130 transmits the selected state signals to the composite signal generation portion 140.

The composite signal generation portion 140 determines a logical operation equation including the state signals received from the state signal generation portion 130, on the basis of a logical operation signal in the received setting signal, and generates a composite signal by the logical operation equation. The composite signal generation portion 140 transmits the generated composite signal to the output portion 150.

The output portion 150 transmits the generated composite signal to the display portion 220 of the external apparatus 200.

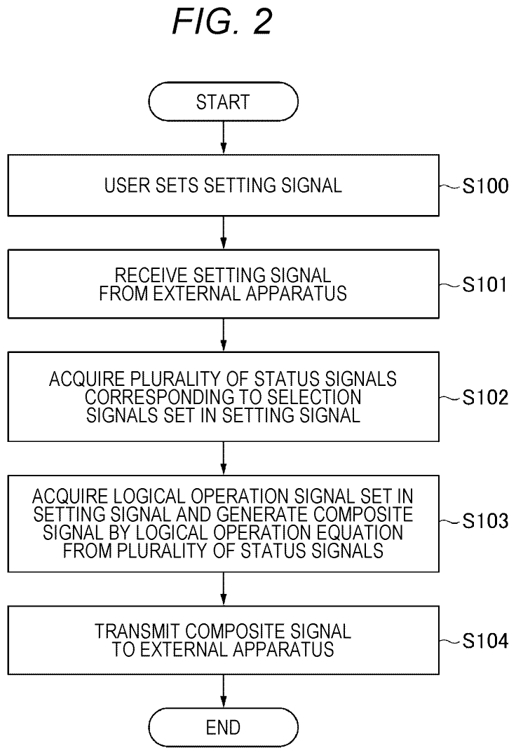

FIG. 2 is a flowchart illustrating a process of generating a composite signal. Firstly, the user sets a setting signal for generating a desired composite signal in the setting portion 210 of the external apparatus 200 upon setup of the motors 300 (S100). The setting signal includes a plurality of selection signals and a logical operation signal.

The selection signal is a signal indicating at least one of the state of the motor and the state of the motor control apparatus. Specifically, the selection signal is a signal selected from, for example, a position signal, alarm signal, temperature data signal, and in-position signal described below of the motor 300, an alarm signal and temperature data signal of the motor control apparatus 100, a position signal of the limit switch 400, a voltage signal of the power source 500, and a motor excitation turn-on signal and emergency shutdown signal to be transmitted from the external apparatus 200 to the motor control apparatus 100. The logical operation signal includes, for example, logical disjunction and/or logical conjunction. The logical operation signal is a signal indicating a logical operation equation related to an operation of logical disjunction and/or logical conjunction on which selection signal and which selection signal.

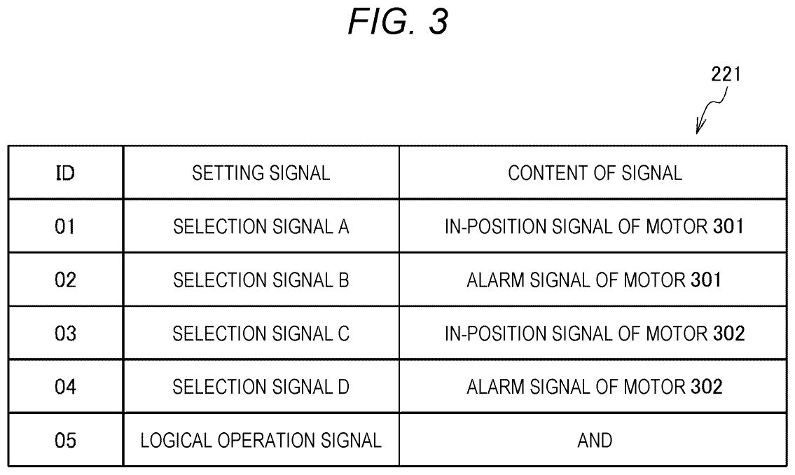

FIG. 3 illustrates an example of a user setting screen 221 displayed on the setting portion 210 of the external apparatus 200. In the exemplification of FIG. 3, the setting signal includes four selection signals A to D, and one logical operation signal. The user uses the user setting screen 221 to select the four selection signals A to D and the one logical operation signal from a plurality of candidates for the selection signals and the logical operation signal, and sets the four selection signals and the one logical operation signal. In the exemplification of FIG. 3, an in-position signal of a motor 301 is set as the selection signal A. An alarm signal of the motor 301 is set as the selection signal B. An in-position signal of a motor 302 is set as the selection signal C. An alarm signal of the motor 302 is set as the selection signal D. Moreover, logical conjunction (AND) is set as the logical operation signal. Note that the motors 301 and 302 indicate motors that are different from each other.

The in-position signal of the motor is a binary signal indicating whether or not the positioning of the motor 300 (301 or 302) has been completed. For example, if the positioning of the motor 300 (301 or 302) has not been completed, the in-position signal of the motor is zero. If the positioning of the motor 300 (301 or 302) has been completed, the in-position signal of the motor becomes one. The alarm signal of the motor is a binary signal indicating whether or not an alarm is occurring in the motor 300 (301 or 302). For example, if an alarm is not occurring in the motor 300 (301 or 302), the alarm signal is one. If an alarm has occurred in the motor 300 (301 or 302), the alarm signal becomes zero.

Return to the description of FIG. 2. The receiving portion 110 of the motor control apparatus 100 receives the setting signal set by the user from the setting portion 210 of the external apparatus 200 (S101).

Next, the state signal generation portion 130 of the motor control apparatus 100 acquires a plurality of state signals corresponding to the selection signals set in the setting signal, and transmits the plurality of state signals to the composite signal generation portion 140 (S102). Here, the state signal generation portion 130 acquires the in-position signal of the motor 301 as the selection signal A, the alarm signal of the motor 301 as the selection signal B, the in-position signal of the motor 302 as the selection signal C, and the alarm signal of the motor 302 as the selection signal D from signals indicating the states of the motors, which are acquired from the plurality of motors 300 (301 and 302), and transmits the signals to the composite signal generation portion 140.

Next, the composite signal generation portion 140 acquires the logical operation signal set in the setting signal, generates a composite signal by a logical operation equation including the plurality of state signals received from the state signal generation portion 130, and transmits the composite signal to the output portion 150 (S103). An example of the logical operation equation is given by equation 1 below.

Composite signal=A AND B AND C AND D (Equation 1)
where A, B, C, and D are the plurality of state signals, and AND is logical conjunction.

If the user sets the setting signal on the user setting screen 221 as illustrated in FIG. 3, A is the in-position signal indicating the completion of positioning of the motor 301, B is the alarm signal of the motor 301, C is the in-position signal indicting the completion of positioning of the motor 302, and D is the alarm signal of the motor 302 in equation 1. In this case, if the positioning of the motors 301 and 302 has been completed, and if an alarm is not occurring in the motors 301 and 302, each of A, B, C, and D is one, and the composite signal being the logical conjunction of A, B, C, and D is one. Moreover, if the positioning of at least one of the motors 301 and 302 has not been completed, or if an alarm is occurring in at least one of the motors 301 and 302, at least one of A, B, C, or D is zero. Therefore, the composite signal being the logical conjunction of A, B, C, and D is zero.

The output portion 150 transmits the generated composite signal to the display portion 220 of the external apparatus 200 (S104). The display portion 220 displays an image based on the transmitted composite signal for the user. Consequently, the user can recognize the states of a plurality of apparatuses such as the plurality of motors 300 (301 and 302), the motor control apparatus 100, and/or the power source 500 by checking one composite signal. In a case of the above-mentioned plurality of state signals A, B, C, and D, the user can recognize whether or not the positioning of the motors 301 and 302 has been completed without occurrence of an error by checking one composite signal. In other words, the user can recognize, for example, whether or not the plurality of motors has completed the transfer of a target object normally by checking one composite signal.

Moreover, the output portion 150 is simply required to send, to the display portion 220, not the plurality of state signals A, B, C, and D but only one composite signal. Hence, signal wiring between the output portion 150 and the display portion 220 can be reduced.

As described above, the motor control apparatus 100 according to the embodiment can generate a composite signal indicating the current states of, for example, the motors 300 (301 and 302) and/or the motor control apparatus 100, the composite signal being desired by the user. Consequently, the user can recognize the states of a plurality of apparatuses such as the plurality of motors 300 (301 and 302), the motor control apparatus 100, and/or the power source 500 by checking one composite signal. Moreover, the motor control apparatus 100 according to the embodiment is simply required to transmit only one composite signal to the external apparatus 200. Hence, the number of wires between the motor control apparatus 100 and the external apparatus 200 can be reduced.

Note that in FIG. 3 described above, the example where only a single operator is specified is illustrated. However, the operator specified by the user is not limited to a single operator. The setting portion 210 may be configured in such a manner as to accept a logical operation equation itself inputted by the user.

Moreover, in equation 1 described above, the example of the composite signal including the in-position signal and the alarm signal is given. However, the composite signal is not limited to the in-position signal and the alarm signal. For example, the composite signal may be an in-position composite signal indicating completion of a positioning operation on all the motors, or may be an alarm composite signal indicating an abnormal state of at least one of the plurality of motors.

Up to this point the embodiments according to the present disclosure have been described. However, it is needless to say that the technical scope of the present disclosure should not be construed in a limited manner by the detailed description. The above-described embodiments are mere exemplifications. Those skilled in the art understand that the above-described embodiments can be modified in various manners within the scope of the disclosure of the claims. The technical scope of the present disclosure should be determined on the basis of the scope of the disclosure of the claims and the scope of equivalents thereof.

The foregoing detailed description has been presented for the purposes of illustration and description. Many modifications and variations are possible in light of the above teaching. It is not intended to be exhaustive or to limit the subject matter described herein to the precise form disclosed. Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims appended hereto.

What is claimed is:

1. A motor control apparatus comprising:
a receiving portion configured to receive a setting signal from an external apparatus of the motor control apparatus; and
a composite signal generation portion configured to generate a composite signal from a plurality of state signals indicating at least one of a state of a plurality of motors and a state of the motor control apparatus, wherein
the composite signal generation portion is configured to determine a logical operation equation including the plurality of state signals on the basis of the setting signal, and generate the composite signal by the logical operation equation.

2. The motor control apparatus according to claim 1, wherein the state signals include a state signal indicating the state of the motor control apparatus.

3. The motor control apparatus according to claim 1, further comprising an output portion configured to output the composite signal to the external apparatus.

4. The motor control apparatus according to claim 1, wherein the state signals are binary signals.

5. The motor control apparatus according to claim 1, wherein the composite signal is an in-position composite signal indicating completion of a positioning operation on all the motors.

6. The motor control apparatus according to claim 1, wherein the composite signal is an alarm composite signal indicating an abnormal state of at least one of the plurality of motors.

7. A motor control apparatus comprising:
a receiving portion configured to receive a setting signal from an external apparatus of the motor control apparatus; and
a composite signal generation portion configured to generate a composite signal from a plurality of state signals indicating at least one of a state of a motor and a state of the motor control apparatus, wherein
the composite signal generation portion is configured to determine a logical operation equation including the plurality of state signals on the basis of the setting signal, and generate the composite signal by the logical operation equation.

8. The motor control apparatus according to claim 7, wherein the state signals include a state signal indicating the state of the motor control apparatus.

9. The motor control apparatus according to claim 7, further comprising an output portion configured to output the composite signal to the external apparatus.

10. The motor control apparatus according to claim 7, wherein the state signals are binary signals.

11. The motor control apparatus according to claim 7, wherein the composite signal is an in-position composite signal indicating completion of a positioning operation on the motor.

12. The motor control apparatus according to claim 7, wherein the composite signal is an alarm composite signal indicating an abnormal state of the motor.
